(19) United States
(12) Patent Application Publication
(10) Pub. No.: US 2024/0200199 A1
(43) Pub. Date: Jun. 20, 2024

(54) COATED FLAT STEEL PRODUCT AND METHOD FOR THE PRODUCTION THEREOF

(71) Applicant: ThyssenKrupp Steel Europe AG, Duisburg (DE)

(72) Inventors: Daniel SCHWANKE, Oberhausen (DE); Stefan BIENHOLZ, Bochum (DE)

(73) Assignee: ThyssenKrupp Steel Europe AG, Duisburg (DE)

(21) Appl. No.: 18/279,437

(22) PCT Filed: Mar. 14, 2022
(86) PCT No.: PCT/EP2022/056503

§ 371 Date: Aug. 30, 2023

(30) Foreign Application Priority Data
Mar. 24, 2021 (DE) 10 2021 107 330.8

(51) Int. Cl. C23C 28/02; B32B 15/01; C21D 7/02; C21D 7/13; C22C 18/00; C22C 38/00; C22C 38/06; C22C 38/34; C22C 38/38; C23C 2/06; C23C 2/28; C23C 14/16; C25D 3/22

(52) U.S. Cl. CPC C23C 28/021; B32B 15/013; C21D 7/02; C21D 7/13; C22C 18/00; C22C 38/002; C22C 38/06; C22C 38/34; C22C 38/38; C23C 2/06; C23C 2/28; C23C 14/16; C25D 3/22

(57) ABSTRACT

The present disclosure relates to a flat steel product having a tensile strength Rₘ of at least 800 MPa and coated with a metal covering, wherein the metal covering consists of a system having the elements zinc and manganese and having been deposited from the gas phase. Furthermore, the present disclosure also relates to a method for its production.

### TECHNICAL FIELD

The invention relates to a flat steel product having a tensile strength Rₘ of at least 800 MPa that is coated with a metal covering and also to a method for its production.

### TECHNICAL BACKGROUND

Common knowledge from the prior art are steels having metal coverings that are deposited from the gas phase, as described for example in German laid-open specification DE 1 621 376 A. Comparable metal coverings deposited from the gas phase and intended for hot forming, where the steels and, respectively, the components produced by hot forming and (press) hardening have a final tensile strength of 1500 MPa or more, are known from German laid-open specifications DE 10 2014 004 652 A1 and DE 10 2018 128 131 A1.

In higher-strength multiphase steels, especially in what are known as quench and partitioning (Q&P) steels, with zinc-containing metal coverings there is an increased propensity toward cracking due to liquid metal embrittlement (LME) on resistance spot welding (RSW). LME-induced cracking during RSW is a topic in a host of publications, with international laid-open specifications WO 2017/234839 A1 and WO 2018/234938 A1 being among those to be concerned with LME in conjunction with RSW, describing extremely high-strength Q&P steels having zinc coverings. From these publications it is further apparent that molybdenum, chromium and silicon as alloy element promote LME as the amount thereof in the sheet steel increases, it being proposed here, therefore, that annealing, to establish the Q&P structure, is carried out in an atmosphere in which the partial pressure of oxygen is established in such a way via targeted control of the dew point and diffusion of oxygen into the sheet steel is promoted during the annealing phase, causing binding of elements including silicon, in the form of silicon dioxide, in the near-surface region of the sheet steel, and so making it possible to reduce the elemental silicon content under the zinc coating in the sheet steel and hence in turn to increase the resistance to LME. The teaching of these publications is aimed at the defined establishment of the alloy elements silicon, chromium and molybdenum and hence of the corresponding structure in the sheet steel region 0 to 100 μm below the zinc covering, in order to be able to provide a high level of resistance to LME for the zinc-coated Q&P steel. It is mentioned only in passing that according to one alternative, the zinc covering may also be deposited from the gas phase.

Additionally known from the prior art is that in steels with increasing strengths, LME sensitivity rises in conjunction with zinc-based coverings and hence during RSW problems arise due to cracking because during the RSW, zinc in the covering is liquified, penetrates into the substrate and may become deposited at the grain boundaries of the steel, so making it more susceptible to brittle fracture and possibly leading in the subsequent application to premature failure under loading.

Further approaches are known for suppressing the problem of LME by increasing the contact areas of the welding electrode or, respectively, by modifying the combination of materials and sheet thicknesses—cf. patent specification U.S. Pat. No. 9,333,588 B2.

### SUMMARY OF THE INVENTION

It is an object of the invention, therefore, to provide a flat steel product having a tensile strength Rₘ of at least 800 MPa in conjunction with a metal covering and also to specify a corresponding method for its production, enabling a reduction in LME-induced cracking propensity during RSW, without having to take corresponding measures and/or make adaptations in the ongoing (standard) processes of the kind of measures and/or adaptations described in the prior art.

This object is achieved, according to a first aspect of the invention, by a flat steel product having the features of claim 1.

The invention provides a flat steel product having a tensile strength Rₘ of at least 800 MPa and coated with a metal covering wherein the metal covering consists of a system having the elements zinc and manganese that is (has been) deposited from the gas phase.

Essential to the invention is that the metal covering consists of a system having the elements zinc and manganese, with zinc consequently contributing to cathodic corrosion control and manganese having a positive influence on the LME cracking propensity of the steel (substrate), since the presence of manganese in the metal covering system allows the melting temperature of the system to be increased, with the consequent possibility of reduced and/or retarded melting of the system during RSW. As a result, the susceptibility to brittle fracture can be lowered.

It has surprisingly been observed, furthermore, that the metal covering deposited from the gas phase, as a result of the method, typically does not provide any hydrogen which, in the case of other coating methods, especially electrolytic coating, may arise as a result of the process and become included in the metal lattice. In the case of steels having tensile strengths of at least 800 MPa and higher, the included hydrogen can lead to hydrogen-induced brittle fractures.

The principle of deposition from the gas phase, CVD (chemical vapor deposition) or PVD (physical vapor deposition) for example, is prior art. The PVD method is preferred. This technology should not be confused either with application of coverings via electrolytic coating or with application of coverings via hot-dip coating.

The flat steel product of the invention has a tensile strength Rₘ of at least 800 MPa, more particularly at least 850 MPa, preferably at least 910 MPa, more preferably at least 950 MPa. The tensile strength Rₘ of the flat steel product of the invention is not more than 1700 MPa, more particularly not more than 1600 MPa, preferably not more than 1520 MPa, more preferably not more than 1490 MPa. The tensile strength Rₘ may be determined in a tensile test to DIN EN ISO 6892-1:2017. The flat steel product of the invention is employed exclusively for cold forming application and not for hot forming applications (including hardening), and so the corresponding properties are already present in the flat steel product prior to cold forming.

According to one configuration, the system includes a layer of a zinc-manganese alloy. From the gas phase, therefore, the system is deposited in one step and a layer of a zinc-manganese alloy is generated on the flat steel product. The metal covering on the flat steel product therefore consists of a single-layer alloy of zinc and manganese, deposited from the gas phase. In this case the deposition is controlled in particular in such a way that in the zinc-manganese alloy a zinc content of between 10 and 90 wt % and a manganese content of between 90 and 10 wt % are established. A manganese content of at least 10 wt % is needed in order to ensure reduced propensity to LME cracking during RSW, and the amount may be in particular at least 20 wt %, preferably at least 30 wt %, more preferably at least 40 wt %. Conversely, the manganese content in the alloy (layer) is limited to not more than 90 wt %, allowing the metal covering and, respectively, the system to ensure sufficient cathodic corrosion control with at least 10 wt %, more particularly at least 20 wt %, preferably at least 30 wt %, more preferably at least 40 wt % of zinc, since the metal covering or the system is applied from the gas phase with a thickness of between 0.5 and not more than 20 μm, more particularly not more than 15 μm, preferably not more than 10 μm on the flat steel product. The higher the zinc content in the system or, respectively, in the (relatively thin) metal covering, the higher the cathodic corrosion control.

According to an alternative configuration, the system has a layer of manganese and a layer of zinc. The metal covering is therefore two-layer and consists of a zinc layer and a manganese layer, each deposited from the gas phase. The system is deposited in two steps, by successive deposition first of a layer of manganese on the flat steel product and subsequently a layer of zinc on the layer of manganese. The layer of manganese is therefore disposed on the flat steel product, and the layer of zinc on the layer of manganese. The two layers may each be deposited with a thickness of between 0.5 and not more than 20 μm, more particularly not more than 15 μm, preferably not more than 10 μm, more preferably not more than 7 μm.

In comparison to the one-layer system, the two-layer system has the advantage that the outer layer of zinc affords complete and high-grade cathodic corrosion control and the inner layer of manganese affords a complete barrier during RSW. A disadvantage relative to the one-layer system is that it is necessary to pass through two separate gas-phase stages for the layers to be successively deposited.

According to one configuration, the flat steel product may be either hot-rolled or cold-rolled. The governing factor is the intended use. The hot-rolled flat steel product (hot strip) may have a thickness of between 1.5 and 10 mm. The cold-rolled flat steel product (cold strip) may have a thickness of between 0.5 and 4 mm. The process proceeding from the casting of a melt, in particular with a chemical composition which is cited as preferred below, to give a precursor product, and heating the precursor product to a temperature so that it can be hot-rolled to a flat steel product, is prior art. Where the required minimum tensile strengths are established in the hot strip itself, a corresponding procedure is familiar to the skilled person. If the intention, from the hot strip, is to establish a cold-rolled flat steel product having a minimum tensile strength of 800 MPa, then it is also prior art to subject the hot strip in particular initially to pickling before it is cold-rolled to form a cold strip. In an annealing process subsequently, the desired properties are established. The core of the invention is not the production of the flat steel products with a tensile strength of at least 800 MPa, but rather the specifying of a suitable coating approach which for steels in the specified tensile strength class of 800 MPa and higher is able to counteract the particular LME susceptibility of these tensile strength classes during RSW.

The structure of the flat steel product comprises at least two different phases. The structure therefore contains at least two constituents from ferrite, perlite, martensite, bainite, austenite, retained austenite and/or cementite, and also unavoidable production-related structural constituents. These include, for example, dual-phase steels (DP steels), which have a structure composed of a mixture of hard phases, martensite for example, and soft phases, ferrite for example. Complex-phase steels (CP steels) contain primarily phases of moderate hardness, such as bainite and/or (tempered) martensite, optionally in conjunction with precipitation hardening. Quench&Partitioning (QP steels) contain predominantly martensite (including tempered martensite) and retained austenite. Alternatively or additionally, precipitates may be present in the structure.

According to one configuration, the flat steel product, in addition to Fe and unavoidable production-related impurities, in weight %, consists of
C: 0.001 to 0.50%,
Mn: 0.10 to 3.0%,
Si: 0.01 to 2.0%,
Al: 0.002 to 1.5%,
P: to 0.020%,
S: to 0.020%,
N: to 0.020%,
   optionally one or more alloy elements from the group of (Ti, Nb, V, Cr, Mo, W, Ca, B, Cu, Ni, Sn, As, Co, O, H) with
Ti: to 0.20%,
Nb: to 0.20%,
V: to 0.20%,
Cr: to 2.0%,
Mo: to 2.0%,
W: to 1.0%,
Ca: to 0.050%,
B: to 0.10%,
Cu: to 1.0%,
Ni to 1.0%,
Sn: to 0.050%,
As: to 0.020%,
Co: to 0.50%,
O: to 0.0050%,
H: to 0.0010%.

The object is achieved according to a second aspect of the invention by a method having the features of claim 8.

The method for producing a flat steel product coated with a metal covering and having a tensile strength Rₘ of at least 800 MPa comprises the steps of:
providing a hot-rolled or cold-rolled flat steel product;
coating the flat steel product with a metal covering.

In accordance with the invention, the metal covering consists of a system having the elements zinc and manganese and is deposited from the gas phase on the flat steel product.

### DESCRIPTION OF THE PREFERRED EMBODIMENTS

An assessment of the extent to which the cracks are detrimental to component function cannot be undertaken precisely when considering an RSW weld location. Preventing or at least significantly reducing the cracks during RSW is therefore of great significance for the application.

From a melt consisting, as well as Fe and unavoidable production-related impurities, in wt %, of C=0.25%, Si=1.5%, Mn=2.2%, Al=0.03%, Cr=0.7%, P=0.005%, a precursor product was cast that was initially hot-rolled to a flat steel product and subsequently cold-rolled to a thickness of 1.5 mm. The cold-rolled flat steel product underwent a Q&P process to establish a structure composed essentially of martensite (including tempered martensite)/bainite and 9% retained austenite (RA) and also unavoidable production-related structural constituents. Samples were taken from the flat steel product thus generated, and were
a) left uncoated;
b) hot-dip-coated on either side with respective zinc coatings (Z) 7 μm thick, with the RA dropping to 7%; a portion of the samples b1) were subjected to additional heat treatment (ZF) at around 630° C. for around 15 s, and the heat treatment/diffusion caused the RA to drop further to 3%;
c) coated electrolytically on either side with a zinc coating (ZE) 6 μm thick;
d) subjected to deposition of a zinc-manganese alloy (ZnMn-PVD) via the gas phase with zinc and manganese simultaneously and with 6 μm on both sides, the deposition being controlled in such a way as to produce a single-layer system with 60 wt % zinc and 40 wt % manganese;
e) subjected first to deposition with a layer of manganese (Mn-PVD) via the gas phase on both sides with 2 μm, followed by deposition atop the layer of manganese with a layer of zinc (Zn-PVD) via the gas phase on both sides with 4 μm, resulting in a two-layer system with an Mn—Zn-PVD coating on the samples.

A further sample was taken from the flat steel product and put forward for tensile testing according to DIN EN ISO 6892-1:2017. A tensile strength Rₘ of 1183 MPa was determined. The flat steel products and samples were coated with the respective metal coverings b) to e) described, with coating taking place on the laboratory scale but nevertheless with the parameters of large-scale line production.

Because of the natural scatter occurring in RSW studies in relation to LME-induced cracking, it would be necessary in general to expend large volumes of material in numerous measurement series. Owing to the poor quantifiability of the LME-associated measurement variables, only qualitative statements can be ascertained for the LME sensitivity of steels within RSW studies. The large materials-related requirement would disqualify testing to the existing level for a laboratory application. For this reason, a testing and optimization concept suitable for the laboratory scale was developed, in the form of an “LME Gleeble hot tensile test”. The test took place on a commercial test apparatus, the Gleeble3500. The processing variables used corresponded to the thermomechanical loads experienced during RSW in the region of crack formation. The tensile velocity used was a consistent 3 mm/s for a measurement length of 10 mm. In order to determine the real strain values in the measured region of the samples, the strain was measured contactlessly by a laser. The heating rate was 1000 K/s. As the temperature interval, the liquidus phase of zinc between 500 and 900° C. in 100° C. steps was used.

Hot tensile tests were carried out for all samples a) to e). After clamping of the samples in the test apparatus, the test chamber was closed and a script programmed in advance was performed as follows. The measurement frequency during the hot tensile tests here was at least 5000 Hz. The samples were heated by conduction and on attainment of the sample testing temperature in the above-stated temperature window between 500 and 900° C., the sample was stretched to failure at the specified tensile velocity. The measurement data harvested were then verified for their quality using the Origin analytical software. The evaluation routine in the hot tensile tests was based on the standard of the tensile test [DIN EN ISO 6892-1:2017]. The raw data from hot tensile tests carried out successfully were converted with computer assistance into a cubic function. The necessary support points and the moment of technical failure of the samples were entered into an evaluation module by the unit operator.

From the individual measurement data, the changes in the mechanical properties and in the fracture behavior were captured as a function of temperature. To improve comparability of the effect of the various metal coverings, so-called relative change curves were generated from the absolute measurement values. The reference variables for the change curves here were, fundamentally, the measurement results for the uncoated samples a). The size of the changes due to the respective metal coverings was determined as a function of temperature and used as a measure of the intensity of the LME effect.

For the samples b) with Z, a sharp reduction in the technical fracture point was determined for all test temperatures. In particular, the strain value of the technical fracture point was reduced by >85% in comparison to the samples a). The samples b1) with ZF showed no substantial changes in the technical fracture point at the test temperatures of 500 and 600° C. This reduction was very pronounced for the other test temperatures (700-900° C.). The behavior displayed by the samples c) with ZE was comparable with that of the samples b). In the case of the samples d) with Zn/Mn alloy-PVD, no significant strain value of the technical fracture point was determined for any of the test temperatures; in comparison to the samples a), the technical fracture point was around <10% lower. For the samples e) with Mn—Zn-PVD, the result was in the same order of magnitude as for the samples d).

The results found for the change in the plastic energy absorption capacity were similar to those found for the change in the technical fracture point. The results confirmed the negative effects by Z of the samples b). Similarly, ZF of the samples b1) showed no limitations on the plastic energy absorption capacity at the test temperatures of 500 and 600° C. This reduction was also very pronounced here for the rest of the test temperatures between 700 and 900° C. The behavior exhibited by the samples c) was comparable to that for the samples b). In the case of the samples d), a slight reduction in the plastic energy absorption capacity was in evidence at the test temperatures between 600 and 800° C. The rest of the test temperatures showed virtually no effect of the metal covering. The samples e) as well were in the same order of magnitude as the samples d).

The change in the constriction at break likewise showed results similar to those for the change in the technical fracture point and in the plastic energy absorption capacity. When considering the constriction at break, it should be noted that, unlike the technical sample failure and the plastic energy absorption capacity, this is a local measurement variable.

The results confirm the negative effect by Z of the samples b) on the constriction at break as a result of brittle fracture faces, consistently for all test temperatures. In the case of ZF of the samples b1), there were no limitations on the constriction at break at the test temperatures of 500 and 600° C. Beyond a test temperature of 700° C., however, a severe brittle fracture behavior at the fracture face was detected. Here again, the samples c) with ZE showed a behavior similar to that of the samples b). In the case of the samples d) with Zn/Mn-PVD, a slight reduction in the constriction at break was in evidence at a test temperature of 800° C. For the test temperatures of 600, 800 and 900° C., cracks were detected behind the actual fracture face. The results exhibited by the samples e) with Mn—Zn-PVD were similar to those for the samples d).

Studying the effect of the different metal coverings on the technical fracture point, the plastic energy absorption capacity and the constriction at break shows that LME-induced crack formation cannot be ruled out wholesale for zinc-containing metal coverings.

In the hot tensile test, the samples b) to e) with a wide variety of different metal coverings were studied for their “LME sensitivity”. Serving as a reference were the uncoated samples a). In detachment from this, it is also possible for further coatings, not stated here, and also different steel designs, to be studied, without having to go through complicated and quantitative RSW studies. Here in particular it is possible to study all LME-sensitive steel materials having tensile strength Rₘ of at least 800 MPa.

Prevention or reduction of crack frequency, crack depth and crack length is forecast if, for the change in the technical fracture point over the temperature range from 500 to 900° C., the following is true:

f(x)=0.1375·x−58.75

or if, in the testing range from 500 to 900° C., using a consistent temperature step size, the following is true in the test interval:

f(x)=7.25·√x−155

or if, for the sum total of all measurement values in the temperature range from 500 to 900° C., using a consistent temperature step size, the following is true in the test interval:

Σf(x)/n<40.

In the experimental RSW studies, process parameters and material-thickness combinations are used, among other factors, which in the case of the zinc-coated sample lead with high probability and high reproducibility to LME cracks. The thermomechanical loadings applied in the Gleeble method are a model here of the average thermomechanical loads applying in the RSW experiments.

Validation is seen as successful if the “LME sensitivity” in the Gleeble method is comparatively small and if significantly reduced crack frequencies and lower crack depths (or no cracks at all) are detected in the RSW studies.

Experimental RSW studies were carried out on the samples a) to e). The parameters of the RSW studies are set out in table 1. Manufacturing the sample series for the RSW studies took place immediately after the current strength required in order to achieve the target spot diameter had been determined. The welding electrodes were subsequently milled by means of a mobile cap milling apparatus within the welding machine, and were conditioned with three weldings. Samples for which weld splatters occurred were discarded. Comparability of welding results was rated as good on the basis of the consistent spot diameters, current strengths and processing variables.

TABLE 1
Reference series

| Number of samples per series | n = 10 | |
|---|---|---|
| LME test specimen, samples b) to e) | Samples b) to e) (t = 1.5 mm) | |
| Workpieces to be joined | DX56D + Z100 (t = 2.0 mm) | |
| Current strength [A] | Adapted to target spot diameter | |
| Electrode form | F-1-5.5 | |
| Preliminary hold time [ms] | 1000 | ms |
| Main hold time [ms] | 300 | ms |

| | |
|---|---|
| Number of series | 2 |

Series 1

| | | |
|---|---|---|
| Electrode force [kN] | 4.5 | kN |
| Welding time [ms] | 600 | ms |
| Target spot diameter [mm] | 6.4 ± 0.3 | mm |

| | |
|---|---|
| Number of sheets | 2 |

Series 2

| | | |
|---|---|---|
| Electrode force [kN] | 5.2 | kN |
| Welding time [ms] | 900 | ms |
| Target spot diameter [mm] | 7.6 ± 0.3 | mm |

| | |
|---|---|
| Number of sheets | 3 |

The results from the RSW studies were in good agreement with the forecasts from the Gleeble hot tensile tests, although complete quantitative correlation was not possible, owing to the scatier in the study results that is inherent to the RSW process. In order to improve the accuracy of the crack testing, all of the welded samples were delaminated prior to crack characterization. For all of the samples, crack characterization took place on the top side of the LME test specimen, using a macroscope. The crack frequency of a sample series here was determined using the binary classification (crack/no crack). For analysis of the crack morphology, digital measurement took place and the LME cracks were counted on the basis of three selected samples per sample series. For determining the crack depth, at least three polished metallographic sections were prepared. The position of the section was marked on the sample and ran centrally through the longest crack on the weld location surface. Furthermore, it was also necessary to determine the average crack depth in order to confirm successful qualitative transposition of the Gleeble findings.

The highest crack frequency and the deepest and longest cracks were expected for the samples b) coated with Z. As a result of the high active loadings in the defined reference welding tasks, no improvement in crack frequency by the samples b1) coated with ZF was forecast, since the ascertained critical temperature of 700° C. may be exceeded at many points on the weld location surface during the welding process. The highest crack frequency and the longest cracks were found for the welded samples b) and b1), and in the case of b1) series 2 had the highest crack frequency, but the average crack length was lower than for the samples b1) of series 1 and for the samples b) of series 1 and 2. These results were in good agreement with the verified strong LME effect in the Gleeble method. For the samples c) as well, the result was similar as for the samples b). In terms of the welding results, no cracks were detected in series 1 for samples d) and e). In series 2, small cracks were found in the region of electrode pressure application only for the samples e). A possible explanation for this might be that the penetrating welding electrode ruptured the manganese layer in these regions and allowed the liquid zinc to penetrate. In the case of the samples d) which had a small fraction of liquid zinc phases in the metallic covering system, no cracks occurred in series 2 either. On the basis of the results for samples d) and e), therefore, a significantly reduced crack frequency and extent of cracking were forecast in the RSW welding tests. The results from the RSW tests show good agreement with the forecasts from the Gleeble tests, but cannot be fully correlated quantitatively owing to the scatter in the study results that is inherent to the RSW process.

The RSW results especially for the samples e) of series 2 showed that LME cracking cannot be ruled out when welding an LME-sensitive substrate material with a zinc-containing coating, and yet the number and extent of the cracks can be reduced significantly relative to pure zinc layers.

1. A flat steel product having a tensile strength Rₘ of at least 800 MPa, determined according to DIN EN ISO 6892-1:2017, which is coated with a metal covering, the flat steel product comprising at least two different phases in the structure, wherein the metal covering consists of a system having the elements zinc and manganese and having been deposited from the gas phase.

2. The flat steel product as claimed in claim 1, wherein the system includes a layer of a zinc-manganese alloy.

3. The flat steel product as claimed in claim 2, wherein the zinc-manganese alloy has a zinc content of between 10 and 90 w % and a manganese content of between 90 and 10 w %.

4. The flat steel product as claimed in claim 1, wherein the system includes a layer of manganese and a layer of zinc.

5. The flat steel product as claimed in claim 4, wherein the layer of manganese is disposed on the flat steel product and the layer of zinc on the layer of manganese.

6. The flat steel product as claimed in claim 5, wherein the flat steel product is a hot-rolled or cold-rolled product.

7. The flat steel product as claimed in claim 6, wherein the flat steel product, in addition to Fe and unavoidable production-related impurities, in weight %, consists of
C: 0.001 to 0.50%,
Mn: 0.10 to 3.00%,
Si: 0.01 to 2.0%,
Al: 0.002 to 1.5%,
P: to 0.020%,
S: to 0.020%,
N: to 0.020%.

8. A method for producing a flat steel product coated with a metal covering and having a tensile strength Rₘ of at least 800 MPa, determined according to DIN EN ISO 6892-1:2017, the flat steel product comprising at least two different phases in the structure, comprising the steps of:
providing a hot-rolled or cold-rolled flat steel product;
coating the flat steel product with a metal covering;
wherein the metal covering consists of a system having the elements zinc and manganese and is deposited from the gas phase on the flat steel product.

9. The method as claimed in claim 8, wherein the system is deposited in one step and generates a layer of a zinc-manganese alloy on the flat steel product.

10. The method as claimed in claim 9, wherein the deposition is controlled in such a way that in the zinc-manganese alloy a zinc content of between 10 and 90 w % and a manganese content of between 90 and 10 w % are established.

11. The method as claimed in claim 8, wherein the system is deposited in two steps, by successive deposition first of a layer of manganese on the flat steel product and subsequently of a layer of zinc on the layer of man.

12. The flat steel product as claimed in claim 7 further comprising:
one or more alloy elements from the group of (Ti, Nb, V, Cr, Mo, W, Ca, B, Cu, Ni, Sn, As, Co, O, H) with
Ti: to 0.20%,
Nb: to 0.20%,
V: to 0.20%,
Cr: to 2.0%,
Mo: to 2.0%,
W: to 1.0%,
Ca: to 0.050%,
B: to 0.10%,
Cu: to 1.0%,
Ni: to 1.0%,
Sn: to 0.050%,
As: to 0.020%,
Co: to 0.50%,
O: to 0.0050%,
H: to 0.0010%.
